(19) United States
(12) Patent Application Publication
(10) Pub. No.: US 2026/0344358 A1
(43) Pub. Date: Oct. 29, 2026

(54) VENTED HEATER RINGS FOR PROCESSING CHAMBERS

(71) Applicant: Applied Materials, Inc., Santa Clara, CA (US)

(72) Inventors: Benjamin Ean THAM, Elk Grove, CA (US); Zhepeng CONG, San Jose, CA (US); Paul L. BRILLHART, Pleasanton, CA (US)

(21) Appl. No.: 19/192,514

(22) Filed: Apr. 29, 2025

(51) Int. Cl. H10P 72/76; H05B 6/10; H10P 72/00

(52) U.S. Cl. CPC H10P 72/7611; H05B 6/105; H10P 72/0402; H10P 72/0436

(57) ABSTRACT

An embodiment of a heater ring for a substrate processing chamber includes a body having a central axis an upper surface and a lower surface opposite the upper surface along the central axis and an inner flange defined on a radially inner side of the body relative to the central axis. In addition, the heater ring includes a radially outer flange defined on a radially outer side of the body relative to the central axis and one or more fluid flow paths extending axially between the upper surface and the lower surface that are radially positioned between the inner flange and the radially outer flange.

### BACKGROUND

### Field

Embodiments disclosed herein generally relate to fluid flow in substrate processing chambers. More particularly, embodiments disclosed herein relate to systems for pressure balancing in such processing chambers.

### Description of the Related Art

Semiconductor substrates are used in a wide variety of applications, including the fabrication of integrated electronic devices and microelectronic devices. Fabrication of a semiconductor substrate may include a number of different processing steps. For instance, one such processing operation may include depositing a material, such as a dielectric material or a conductive metal (e.g., metal), on a surface (e.g., such as an upper surface) of the substrate. Epitaxy is an example deposition process that may be used to grow a thin, of material, usually of silicon or germanium on a surface of a substrate. The material may be deposited in a lateral flow chamber by flowing a process fluid parallel to the surface of a substrate, and thermally decomposing the process gas to deposit the material on the surface.

### SUMMARY

Some embodiments disclosed herein are directed to a processing chamber for a substrate that includes a chamber body having a central axis and defining a processing region therein, a liner positioned in the processing region, and a heater ring supported on the liner, the heater ring including an inner flange on a radially inner side thereof. Further, the processing chamber includes a susceptor positioned in the processing region, the susceptor including a top surface that is configured to support the substrate and a radially outer flange positioned radially outside of the top surface, the radially outer flange being at least partially radially overlapped with the inner flange of the heater ring. In addition, the processing chamber further includes one or more axially oriented fluid flow paths that extend through the heater ring, wherein the one or more fluid flow paths are positioned radially outside of the inner flange.

Some embodiments disclosed herein are directed to a heater ring for a substrate processing chamber that includes a body having a central axis, an upper surface, and a lower surface opposite the upper surface along the central axis. In addition, the heater ring includes an inner flange defined on a radially inner side of the body relative to the central axis. Further, the heater ring includes a radially outer flange defined on a radially outer side of the body relative to the central axis and one or more fluid flow paths extending axially between the upper surface and the lower surface that are radially positioned between the inner flange and the radially outer flange.

Some embodiments disclosed herein are directed to a processing chamber for a substrate that includes a chamber body having a central axis and defining a processing region therein. The chamber body includes a process gas inlet on a first radial side of the chamber body and a process gas outlet on a second radial side of the chamber body, the second radial side of the chamber body being radially opposite the first radial side of the chamber body. Further, the processing chamber includes a heater ring supported in the processing region, the heater ring including an inner flange on a radially inner side thereof. In addition, the processing chamber includes a susceptor that is configured to support the substrate. The susceptor divides the processing region into an upper chamber axially above the heater ring and a lower chamber below the heater ring. In addition, the processing chamber includes a first flow path between the lower chamber and the upper chamber that is at least partially defined between the heater ring and the susceptor and one or more second fluid flow paths between the lower chamber and the upper chamber that extend vertically through the heater ring, wherein the one or more second fluid flow paths are positioned on the second radial side of the chamber body.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, as the disclosure may admit to other equally effective embodiments.

FIG. 1 is a schematic cross-sectional view of a processing chamber, according to one or more embodiments disclosed herein.

FIG. 2A is an enlarged cross-sectional view of portion A in FIG. 1 that shows a vented heater ring according to one or more embodiments disclosed herein.

FIG. 2B is a perspective view of the vented heater ring of FIG. 2A, according to one or more embodiments disclosed herein.

FIG. 3A is an enlarged cross-sectional view of portion A in FIG. 1 that shows a vented heater ring according to one or more embodiments disclosed herein.

FIG. 3B is a perspective view of the vented heater ring of FIG. 3A, according to one or more embodiments disclosed herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Epitaxial deposition is used to grow a thin film on a substrate, such as a substrate of a semiconductor device. Film quality in epitaxial growth is influenced by fluid (e.g., gas) flow during film deposition. For example, purge gas flow within a lower portion of a processing chamber may be used to help prevent or reduce the flow of process gas or diffusion of process gas into the lower portion. Gas exchange between the process gas flow and purge gas flow may be detrimental to the deposition process due to pressure differentials between an upper portion and lower portion of the processing chamber. The pressure differentials between an upper portion and a lower portion of the processing chamber can lead to negative consequences, such as uneven thickness during film deposition, due to hardware movement and/or shifting of the susceptor and preheat ring.

Accordingly, embodiments disclosed herein provide improved control of gas flow within processing chambers, particularly epitaxial processing chambers having process gas flow in an upper portion of the chamber and purge gas flow in a lower portion of the chamber. More specifically, embodiments disclosed herein may provide a vented heater ring which improves gas exchange between the process gas flow in the upper portion and purge gas flow in the lower portion of the processing chamber. Without being limited to this or any other theory, directly venting of purge gas flow from the lower portion of the chamber via embodiments of a vented heater ring disclosed herein provides an improved dynamic pressure balance between the upper and lower portions of the chamber that further improves deposition uniformity and tool uptime for an epitaxial deposition process.

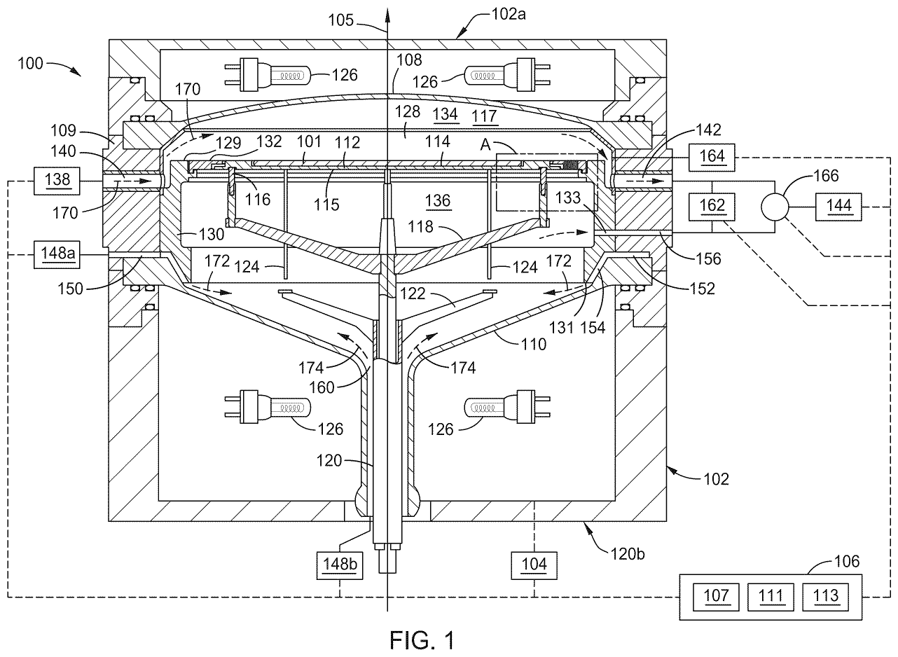

FIG. 1 is a schematic cross-sectional view of a processing chamber 100 including a vented heater ring 132 (or “heater ring 132” or “ring 132”) according to some embodiments. The processing chamber 100 may be used to process one or more substrates 101, including the deposition of a material on an upper surface of the substrate 101. For example, the processing chamber 100 may be adapted to perform an epitaxial deposition process. In some embodiments, the processing chamber 100 may be configured to process a 300 mm substrate; however, other substrates types, shapes, and configurations are contemplated.

The processing chamber 100 generally includes a chamber body 102 (or “body 102”), support systems 104, and a controller 106. The body 102 has a central or longitudinal axis 105 (or “axis 105”). In some embodiments, the axis 105 may be aligned (or substantially aligned) with the force of gravity, such that the axis 105 may also be referred to as a “vertical axis 105.” In addition, the body 102 has a first or upper end 102a and a second or lower end 102b that is spaced from the upper end 102a along the vertical axis 105. Further, the chamber body 102 includes a sidewall 109 that extends axially between the ends 102a, 102b.

The support systems 104 may include components for monitoring and/or executing one or more processes performed using the processing chamber 100, such as film deposition. The controller 106, such as a programmable computer, is coupled to the support systems 104 and is adapted to control the processing chamber 100 and support systems 104. The controller 106 includes a programmable central processing unit (CPU) 107 which is operable with a memory 111 (e.g., non-volatile memory) and support circuits 113. The support circuits 113 are conventionally coupled to the CPU 107 and comprise cache, clock circuits, input/output subsystems, power supplies, and the like, and combinations thereof coupled to the various components of the processing chamber 100.

In some embodiments, the CPU 107 may comprise any form of general purpose computer processor used in an industrial setting, such as a programmable logic controller (PLC), for controlling various monitoring system component and sub-processors. The memory 111, coupled to the CPU 107, is non-transitory and is typically one or more of readily available memory such as random access memory (RAM), read only memory (ROM), floppy disk drive, hard disk, or any other form of digital storage, local or remote.

The memory 111 is in the form of a computer-readable storage media containing instructions (e.g., non-volatile memory), that when executed by the CPU 107, facilitates the operation of the processing chamber 100. The instructions stored in the memory 111 are in the form of a program product such as a program that implements the methods of the present disclosure (e.g., middleware application, equipment software application, etc.). The program code may conform to any one of a number of different programming languages. In one example, the disclosure may be implemented as a program product stored on computer-readable storage media for use with a computer system. The program(s) of the program product define functions of the embodiments (including the methods described herein).

Illustrative computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure.

An upper window 108 (e.g., a dome) and are lower window 110 are position within the body 102 and axially spaced from one another along the axis 105. Specifically, the upper window 108 is positioned more proximate the upper end 102a than the lower end 102b of the body 102, and the lower window 110 is positioned more proximate the lower end 102b than the upper end 102a. A processing region 117 is defined within the body 102, axially between the upper window 108 and the lower window 110 relative to axis 105.

In some embodiments, the upper window 108 and/or the lower window 110 can be in the shape of a dome or can be in another shape, such as flat, concave, or other contour. The upper window 108 and lower window 110 may be formed from an optically transparent material, such as quartz, to facilitate transmission of thermal radiation therethrough.

A susceptor 112 used for supporting the substrate 101 is positioned in the processing region 117. The susceptor 112 may be formed from silicon carbide or graphite coated with silicon carbide. The susceptor 112 has a substrate-receiving top surface 114. The susceptor 112 is rotated and supported by support posts 116, which are coupled to respective supporting arms 118 that extend from a shaft 120. During operations, the substrate 101 positioned on the susceptor 112 may be raised relative to the susceptor 112 by substrate lift arms 122 through lift pins 124.

The processing region 117 is divided into an upper chamber 134 (e.g., a process gas region) and a lower chamber 136 (e.g., a purge gas region). Generally speaking, the upper chamber 134 may extend axially above a plane of the heater ring 132 to the upper window 108, and the lower chamber 136 may extend axially below the plane of the heater ring 132 to the lower window 110, relative to axis 105.

The processing chamber 100 includes a plurality of (such as an array of) radiant heat lamps 126 that may be positioned outside of the processing region 117. The plurality of radiant heat lamps 126 may be configured to heat, among other components, a back side 115 of the susceptor 112 and the heater ring 132 (described in more detail below). Heating of the susceptor 112 and heater ring 132 contributes to thermal decomposition of process gases onto the substrate 101 to form one or more layers on the substrate 101. The radiant heat lamps 126 may be positioned above the upper window 108, below the lower window 110, or both, as shown in FIG. 1. It is contemplated that each of the heat sources described herein can include one or more of: lamp(s), resistive heaters(s), light emitting diodes(s) (LEDs), and/or laser(s). It is further contemplated that other heat sources can be used.

The radiant heat lamps 126 may be arranged in any desired manner around the susceptor 112 to independently control the temperature at various regions of the substrate 101 and facilitate the deposition of a material onto the upper surface of the substrate 101. While not discussed in detail herein, the deposited material may include silicon germanium, gallium arsenide, gallium nitride, or aluminum gallium nitride, among others. The thermal energy output of each of the radiant heat lamps 126 may be controlled using the controller 106. In some embodiments, the radiant heat lamps 126 may be configured to heat the interior of the processing chamber 100 to a temperature within a range of about 200° C. to about 1600° C.

A reflector (not shown) may be optionally placed above the upper window 108 to reflect infrared light that is radiating off the substrate 101 back onto the substrate 101. The reflector may be fabricated from a metal such as aluminum or stainless steel. The efficiency of the reflection can be improved by coating a reflector area with a highly reflective coating such as with gold. The reflector may be coupled to a cooling source (not shown) for providing a cooling fluid such as water to the reflector for cooling the reflector.

An upper liner 128 is disposed below the upper window 108 and is configured to prevent unwanted deposition onto chamber components, such as the sidewall 109 or a peripheral portion of the upper window 108. The upper liner 128 is positioned adjacent to a lower liner 130. The lower liner 130 is configured to fit inside an inner circumference of the sidewall 109. The lower liner 130 is positioned axially between the upper window 108 and lower window 110. In addition, the lower liner 130 extends circumferentially about the lower chamber 136 relative to axis 105. In some embodiments, the upper liner 128 and lower liner 130 may be formed from quartz.

The heater ring 132 is coupled to the lower liner 130, so that the lower liner 130 supports and positions the preheat ring 132 within the processing region 117 of process chamber 100. Specifically, an axially upper end 129 of the lower liner 130 has a profile for receiving and supporting the preheat ring 132 thereon. The preheat ring 132 is configured to be disposed around (such as circumferentially around) the periphery of the susceptor 112 when the susceptor 112 is in a processing position as shown in FIG. 1 wherein the susceptor 112 is at least partially received axially within the heater ring 132. The heater ring 132 also extends radially inwardly from the lower liner 130 so as to at least partially radially overlap the susceptor 112 relative to axis 105. As will be described in more detail herein, radially overlapping portions of the preheat ring 132 and the susceptor 112 are configured to control pressure and gas exchange between the upper chamber 134 and lower chamber 136 during operations. In some embodiments, the heater ring 132 may be formed from silicon carbide; however, other materials are contemplated. In some embodiments, the temperature of the heater ring 132 during operation may be within a range of about 100° C. to about 800° C. Without being limited to this or any other theory, the elevated temperature of the heater ring 132 helps to activate process gases flowing through the upper chamber 134.

During operations, process gas supplied from a process gas supply source 138, is introduced into the upper chamber 134 through a process gas inlet 140 defined through the sidewall 109. The process gas inlet 140 is positioned at least partially between the upper liner 128 and lower liner 130. The process gas inlet 140 is configured to direct the process gas in a generally radially inward direction as indicated by process gas flow 170. During film deposition on the substrate 101, the susceptor 112 may be located in a processing position (shown in FIG. 1), which is adjacent to and at about the same elevation (e.g., along axis 105) as a terminus of the process gas inlet 140, which allows the process gas to flow in a generally planar, laminar condition along a flow path defined at least in part across an upper surface of the substrate 101. While only one process gas inlet 140 is shown, the process gas inlet 140 may include two or more inlets for delivering two or more individual process gas flows having different composition, concentration, partial pressure, density, and/or velocity.

The process gas exits the upper chamber 134 through an exhaust port 142, formed through the sidewall 109 of the processing chamber 102. Thus, the exhaust port 142 may be referred to herein as a “process gas outlet 142.” In some embodiments, the exhaust port 142 may be positioned on an opposite side (such as a radially opposite side) of the chamber body 102 relative to the process gas inlet 140. Thus, the process gas inlet 140 may be positioned on a first radial side (or radial half) of the chamber body 102, and the exhaust port 142 may be positioned on a second radial side (or radial half) of the chamber body 102, the second radial side being radially opposite the first radial side relative to axis 105. Exhaust of the process gas through the exhaust port 142 is facilitated by a vacuum source, such as vacuum pump 144, fluidly coupled to a downstream side of the exhaust port 142.

During operations, purge gas is supplied from one or more purge gas sources 148a and/or 148b to the lower chamber 136. The purge gas sources 148a and 148b may be the same source or different sources as shown. The purge gas may be an inert gas, such as hydrogen or nitrogen. The flow of purge gas in the lower chamber 136 helps prevent or reduce the flow of process gas or diffusion of process gas from the upper chamber 134 to the lower chamber 136. The purge gas may enter the lower chamber 136 through one or both of a side inlet 150 (or purge gas inlet 150) formed in or around the sidewall 109 or a bottom inlet 160 (or bottom purge gas inlet 160) formed in the lower window 110. The side inlet 150 is disposed at an elevation below the process gas inlet 140. A distribution channel 152 is formed radially between the lower liner 130 and the sidewall 109 and vertically between the sidewall 109 and the lower window 110. The distribution channel 152 is in fluid communication with the side inlet 150 for receiving purge gas from the side inlet 150. The distribution channel 152 may extend 360° around the lower liner 130 to distribute purge gas evenly around the lower chamber 136. The distribution channel 152 is fluidly coupled to the lower chamber 136 through a second channel 154. The second channel 154 shown is formed between the lower liner 130 and the lower window 110. The second channel 154 extends radially inwardly towards a lower end 131 of the lower liner 130. Alternatively, the second channel 154 may extend through the lower liner 130. The second channel 154 may be formed as a single annular channel or a plurality of arc-shaped channels. The second channel 154 is disposed at an elevation below the process gas inlet 140. The second channel 154 shown is also disposed at an elevation below the distribution channel 152. Alternatively, the second channel 154 may be disposed at or above the distribution channel 152. The second channel 154 is configured to direct the purge gas into the lower chamber 136 in a generally radially inward direction as indicated by purge gas flow 172.

As previously described, FIG. 1 shows the susceptor 112 in a processing position. In addition, the susceptor 112 may be transitioned to a substrate loading position, in which the susceptor 112 is lowered relative to the heater ring 132 to provide an axial (or vertical) gap between the radially overlapping portions of the susceptor 112 and heater ring 132. With the susceptor 112 in the substrate loading position, the substrate 101 (or another substrate) is configured to be loaded into the chamber body 102 and unloaded from the chamber body 102 through the axial gap between the susceptor 112 and heater ring 132 and through a corresponding opening (not shown) in the lower liner 130. Once a substrate (e.g., substrate 101) is loaded into the chamber body 102 and onto the susceptor 112, the susceptor 112 is raised axially (or vertically) upward from the substrate loading position to the processing position (shown in FIG. 1), such that the susceptor 112 and the heater ring 132 are positioned at an elevation between a terminus of the process gas inlet 140 and a terminus of the second channel 154.

The bottom inlet 160 is disposed between the shaft 120 and the lower window 110. The bottom inlet 160 is in fluid communication (such as direct fluid communication) to the lower chamber 136. The bottom inlet 160 is positioned at an elevation below the second channel 154. The bottom inlet 160 is configured to direct purge gas into the lower chamber 136 in a generally axially (or vertically) upward and radially outward direction as indicated by purge gas flow 174. Purge gas flow 174 from the bottom inlet 160 may be configured to increase the flow of purge gas to a bottom portion of the lower chamber volume 136 compared to purge gas flow 172 alone.

The purge gas exits the lower chamber 136 through an exhaust port, such as purge gas outlet 156 formed through the sidewall 109. The purge gas outlet 156 shown is located opposite (such as radially opposite about the axis 105) the process gas inlet 140. However, the purge gas outlet 156 may be located at any circumferential position along the sidewall 109 with respect to the process gas inlet 140. In one or more embodiments, the lower liner 130 may have a vent 133 for exhausting purge gas directly from the lower chamber 136 and into the purge gas outlet 156. Exhaust of the purge gas from the purge gas outlet 156 is facilitated by a vacuum source, such as vacuum pump 144, fluidly coupled to a downstream side of the purge gas outlet 156.

A differential pressure sensor 162 is configured to measure a pressure differential between the upper chamber 134 and lower chamber 136. The differential pressure sensor 162 is coupled to each of the exhaust port 142 and purge gas outlet 156. The differential pressure sensor 162 may be positioned in or on the sidewall 109. In some embodiments, the differential pressure sensor 162 may be located outside and adjacent the chamber body 102, so that the differential pressure sensor 162 is coupled to the sidewall 109. Measurement data from the differential pressure sensor 162 is communicated to one or both of the controller 106 and a pressure balancing valve 166 which is described in more detail below.

A pressure sensor 164 is configured to measure a pressure in the upper chamber 134. During processing, the pressure in the upper chamber 134 may be about 5 Torr to about 600 Torr. The pressure sensor 164 shown may be located outside and adjacent the chamber body 102 and coupled to the sidewall 109. In some embodiments, the pressure sensor 164 may be positioned in or on the sidewall 109. The pressure sensor 164 may be coupled to the upper chamber volume 134 through the sidewall 109 and the upper liner 128. In some embodiments, the pressure sensor 164 may be coupled to the upper chamber volume 134 through the upper window 108 or between the upper window 108 and the sidewall 109. Measurement data from the pressure sensor 164 is communicated to one or both of the controller 106 and the pressure balancing valve 166. A second pressure sensor (not shown) may be configured to measure a pressure in the lower chamber volume 136. Measurement data from the second pressure sensor (not shown) may be communicated to one or both of the controller 106 and the pressure balancing valve 166.

The pressure balancing valve 166 fluidly couples each of the exhaust port 142 and purge gas outlet 156 to the vacuum pump 144. The pressure balancing valve 166 may be operated by the controller 106 based on data from one or both of the differential pressure sensor 162 or pressure sensor 164. In operation, the pressure balancing valve 166 regulates exhaust of the process gas through the exhaust port 142 and exhaust of the purge gas through the purge gas outlet 156 in order to regulate the pressure differential between the upper chamber volume 134 and lower chamber 136. Pressure balancing between the upper chamber volume 134 and lower chamber volume 136 is able to remove the driving force for gas exchange therebetween. A process design tolerance for the pressure differential may be about +5% or less, such as about +0.1% to about +5%, such as about +2% to about +5%. In one example, for a pressure of 10 Torr in the upper chamber volume 134, the lower chamber volume 136 may be maintained within a range of about 9.9 Torr to about 10.1 Torr (i.e., tolerance of +1%). In one example, the pressure balancing valve 166 is operable to maintain the pressure differential between the upper chamber volume 134 and lower chamber volume 136 at about 10% or less, such as about 5% or less, such as about 1% or less.

The pressure balancing valve 166 may be used to bias the pressure differential towards one of the upper chamber volume 134 or lower chamber volume 136. In one example, the pressure balancing valve 166 is operable to maintain the lower chamber volume 136 at a higher pressure than the upper chamber volume 134. Alternatively, the pressure balancing valve 166 may be operable to maintain the lower chamber volume 136 at a lower pressure than the upper chamber volume 134.

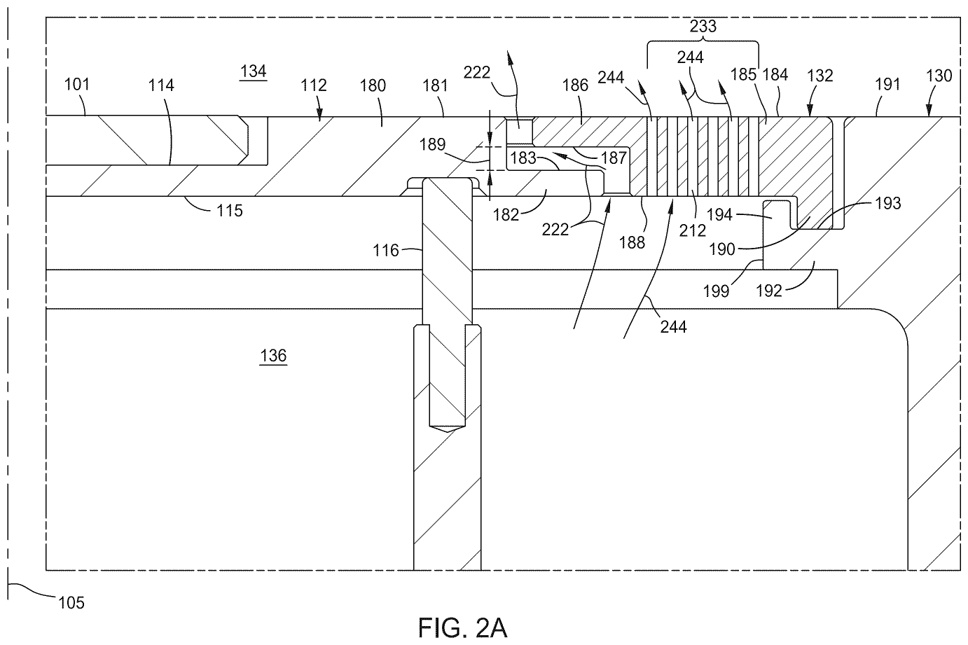

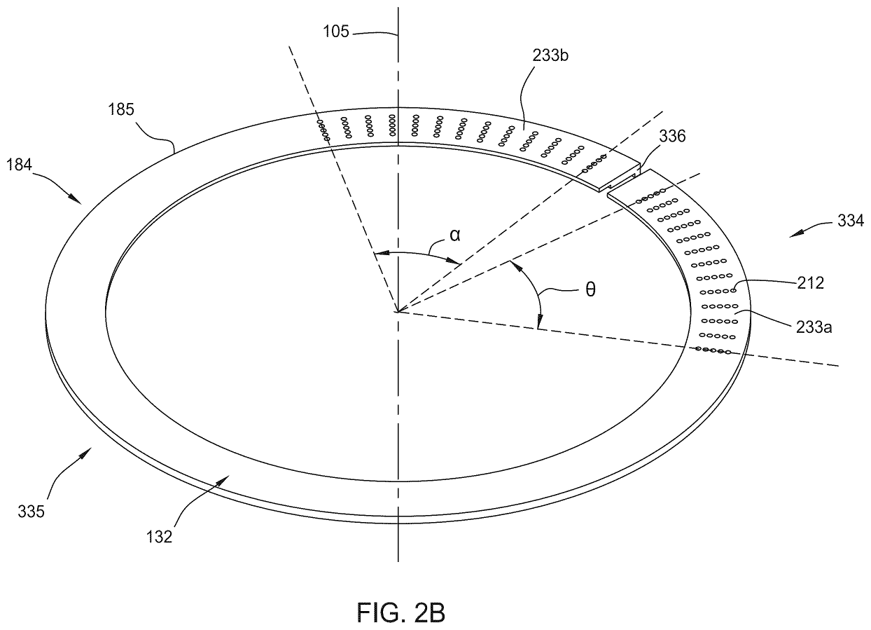

FIG. 2A is an enlarged cross-sectional view of portion A shown in FIG. 1 according to one or more embodiments. As may be appreciated in FIG. 1, the portion A is adjacent to the exhaust port 142. More specifically, the portion A may be located on the same radial side of the axis 105 as the exhaust port 142 about the axis 105, which may be opposite, such as radially opposite, the process gas inlet 140 as previously described.

As shown in FIG. 2A, the susceptor 112 has a raised border 180 (or “border 180”) that extends annularly or circumferentially about the axis 105. The border 180 may project axially upward from the substrate-receiving top surface 114 of the susceptor 112 relative to axis 105 (FIG. 1). The raised border 180 has a planar top surface 181 facing axially upward toward the upper chamber 134.

In addition, the susceptor 112 has an outer flange 182 on a radially outer side (or radially outer flange 182) thereof that extends radially outward from border 180. Specifically, the radially outer flange 182 may include a planar top surface 183 that is positioned axially lower than the planar top surface 181 of border 180. As shown in FIG. 2A, the radially outer flange 182 may at least partially overlap the heater ring 132 in a radial direction relative to axis 105 (FIG. 1).

Referring still to FIG. 2A, the heater ring 132 includes a generally annularly shaped (or ring-shaped) body 184 that has an axially upper surface 185 that axially faces toward the upper chamber 134 and an axially lower surface 188 that faces axially toward the lower chamber 136. In some embodiments, the upper surface 185 of the heater ring 132 may be coplanar with the top surface 181 of the susceptor 112. The body 184 of the preheat ring 132 has an inner flange 186 defined on a radially inner side thereof that extends radially inward toward axis 105. The inner flange 186 defines a lower planar surface 187 (or “lower surface 187”) that faces axially toward the lower chamber 136. The lower surface 187 may be axially positioned above the lower surface 188 of the body 184 relative to axis 105.

The body 184 of the preheat ring 132 also has an outer flange 190 defined on a radially outer side thereof. The outer flange 190 may extend axially outward (e.g., downward) from the lower surface 188. As shown in FIG. 2A, the outer flange 190 may engage or abut with the lower liner 130 and may circumferentially surround an axially extending projection 194 of the lower liner 130. The axially extending projection 194 of lower liner 130 may also at least partially define an axially extending cylindrical surface 199 that extends circumferentially about axis 105 within the lower chamber 136. Thus, the outer flange 190 and the projection 194 may at least partially axially overlap one another relative to axis 105.

The inner flange 186 of body 184 may at least partially radially overlap with the radially outer flange 182 of susceptor 112. Thus, at least a portion of the lower surface 187 of body 184 may axially face or oppose the upper surface 183 of susceptor 112. The inner flange 186 of the preheat ring 132 is positioned axially above the radially outer flange 182 of the susceptor 112 to allow the susceptor 112 to be lowered relative to the preheat ring 132 to the substrate loading position for substrate loading and unloading as previously described.

As shown in FIG. 2A, the inner flange 186 of the heater ring 132 and the radially outer flange 182 of the susceptor 112 may be axially spaced apart from one another so that the surfaces 183, 187 do not contact each other and an axial or vertical gap 189 is defined therebetween. In some embodiments, the vertical gap 189 may be about 1 mm or less, such as from about 0.5 mm to about 1 mm, such as from about 0.6 mm to about 0.8 mm, or such as about 0.6 mm. During operations, the vertical gap 189 may at least partially define a first gas flow path 222 to allow some purge gas to flow from the lower chamber 136 to the upper chamber 134. In some embodiments, the first gas flow path 222 (or flow path 222) may extend circumferentially about the central axis 105 (such as 360° about the axis 105), and thus may be defined on both the first radial side and the second radial side of the chamber body 102 as previously described.

The body 184 of the heater ring 132 also includes a vent portion 233 that is configured to improve the dynamic pressure balancing between the lower chamber 136 and the upper chamber 134 during operations. The vent portion 233 may be radially positioned between the outer flange 190 and inner flange 186. As shown in FIG. 2A, the vent portion 233 may include a plurality of axially oriented holes or ports 212 that define a plurality of second fluid flow paths 244 configured to allow fluid (such as purge gas) to flow from the lower chamber 136 to the upper chamber 134 independently of the first fluid flow path 222 between flanges 186, 182.

In some embodiments, the plurality of vent holes 212 each extend axially between the upper surface 185 and the lower surface 188. In addition, the plurality of vent holes 212 may be distributed in a radial direction between the flanges 186 and 182. Thus, the plurality of vent holes 212 may include a first vent hole 212 that is radially adjacent to a second vent hole 212 along a common radius extending outward from the axis 105. In addition, the plurality vent holes 212 may be distributed in a circumferential direction along the body 184 about the axis 105. Thus, the plurality of vent holes 212 may include a first vent hole 212 that is circumferentially aligned with and adjacent a second vent hole 212.

In some embodiments, the vent holes 212 may all have the same inner diameter or may have different inner diameters. For instance, in some embodiments, the inner diameter of each of the plurality of vent holes 212 may be in a range of from about 2 mm to about 5 mm, such as about 3.5 mm, about 2.5 mm, or about 3.5 mm.

In some embodiments, the plurality of vent holes 212 may each have a circular cross-section in a radially oriented plane relative to the axis 105. In some embodiments, the plurality of vent holes 212 (or one or more of the plurality of vent holes 212) may have a non-circular cross-section along a radially oriented plane relative to axis 105. For instance, in some embodiments, one or more of the plurality of vent holes 212 may have a cross-section that is elliptical, rounded, triangular, rectangular, square, or polygonal, among others. In addition, in some embodiments, one or more of the plurality of vent holes 212 may be elongated or slotted in a radial direction relative to the axis 105. In some embodiments, one or more of the plurality of vent holes 212 may be arranged in a non-symmetrical pattern radially and/or circumferentially about the axis 105. In some embodiments, one or more of the plurality of vent holes 212 may be positioned along a radial outer edge (or perimeter) of the heater ring 132 so that the one or more of the plurality of vent holes 212 defines scallops on the radially outer edge. The non-symmetrical arrangement of the one or more of the plurality of vent holes 212 may be beneficial to make up for other flow non-uniformities in the chamber.

The heater ring 132 may be positioned in the processing chamber 100 relative to the lower liner 130 so that the plurality of vent holes 212 are positioned radially inside of the cylindrical surface 199, so that the plurality of holes 212 are not blocked or occluded by the projection 194 during operations.

FIG. 2B is perspective view of the heater ring 132 of FIG. 2A according to some embodiments. The axis 105 of chamber body 102 is illustrated in FIG. 2B in a position corresponding to when the heater ring 132 is positioned in the chamber body 102 during operations. It should be appreciated that the position of axis 105 in FIG. 2B may also correspond with a position of a central axis of the body 184 of heater ring 132. In some embodiments, the body 184 of preheat ring 132 includes a plurality of circumferentially spaced vent portions 233, with each vent portion including a separate plurality of axially oriented vent holes 212 as previously described. For instance, as shown in FIG. 2B, the body 184 may include a first vent portion 233a and a second vent portion 233b that are circumferentially spaced from one another about axis 105.

In some embodiments, the first vent portion 233a may span circumferentially over an angle θ in a radially oriented plane (not specifically shown) relative to axis 105, and the second vent portion 233b may span circumferentially over an angle α in the radially oriented plane (not specifically shown) relative to axis 105. Thus, the plurality of vent holes 212 of the first vent portion 233a and the plurality of vent holes 212 of the second vent portion 233 may be circumferentially contained within the spans are arcs defined by the angles θ and a, respectively. In some embodiments, the angles θ and a may be the same or different. For instance in some embodiments, the angles θ and a may each be less than 90°, such as in a range from about 30° to about 60°, or such as in a range from about 45° to about 75° about axis 105.

In addition, the first vent portion 233a and the second vent portion 233b may be positioned on or along a first radial side 334 of the heater ring 132. In addition, the heater ring 132 may include a second radial side 335 that is radially opposite the first radial side 334 about the axis 105. In some embodiments, the first radial side 334 and the second radial side 335 may each span circumferentially about 180° about the axis 105. Thus, the first radial side 334 and the second radial side 335 may be referred to herein as “radial halves” or the like. In some embodiments, the first vent portion 233a and the second vent portion 233b may be entirely contained within the first radial side 334. In some embodiments, one or both of the first vent portion 233a and the second vent portion 233b may at least partially extend circumferentially into the second radial side 335, but may have a majority of their spans located in the first radial side 334.

The heater ring 132 may include a radially extending slit 336 so that the body 184 of heater ring 132 is formed as a “split ring.” Without being limited to this or any other theory, the slit 336 may allow the heater ring 132 to thermally expand during operations without causing deformation (e.g., such as axial deformation) of the body 184 or one or more surfaces thereof. In some embodiments, the slit 336 may be circumferentially positioned between the first vent portion 233a and the second vent portion 233b. For instance, in some embodiments, the slit 336 may be circumferentially centered between the first vent portion 233a and the second vent portion 233b.

Referring briefly to FIGS. 1 and 2B, the first radial side 334 of the heater ring 132 may be circumferentially aligned or overlapped with the exhaust port 142. In some embodiments, the slit 336 may be circumferentially aligned (or substantially circumferentially aligned) with the outlet port 142.

In some embodiments, the body 184 may have a total vented flow area that comprises a total cross-sectional flow area of each of the plurality of holes 212 of the first vent portion 233a and the plurality of holes 212 of the second vent portion 233b. In some embodiments, this total vented flow area of the body 184 may be in a range of from about 1000 mm² to about 2000 mm², such as from about 1200 mm² to about 1400 mm², such as from about 1500 mm² to 1800 mm², such as from about 1600 mm² to about 1900 mm².

Referring back to FIGS. 2A and 2B, as explained above, the plurality of holes 212 of the vent portions 233a and 233b may define one or more separate fluid flow paths 244 that are configured to allow fluid (such as purge gas) to flow from the lower chamber 136 to the upper chamber 134 independently of the gas flow path 222 between flanges 186, 182. Thus, fluid flow paths 244 improve gas flow and dynamic pressure balancing between the upper chamber 134 and the lower chamber 136 of the processing chamber shown in FIG. 1 during operations. For instance, if a sudden adjustment is made to the pressure differential valve 166, the second flow paths 244 may allow the resulting pressure differential between the chambers 134, 136 to equalize so as to avoid shifting one or more components (e.g., susceptor 112, heater ring 132, etc.) within the processing region 117.

In addition, because the vented portion(s) 233 (or 233a, 233b) are positioned on or in the first radial side 334 of heater ring 132 that is further aligned with the outlet port 142, the additional flow paths 244 may be positioned proximate the outlet port 142. As a result, the additional flow of purge gas into the upper chamber 134 via the fluid flow paths 244 may be downstream of the substrate 101 relative to the flow of process gas in the upper chamber 134 so that this additional flow of purge gas may not interfere (or may not substantially interfere) with the deposition process as previously described.

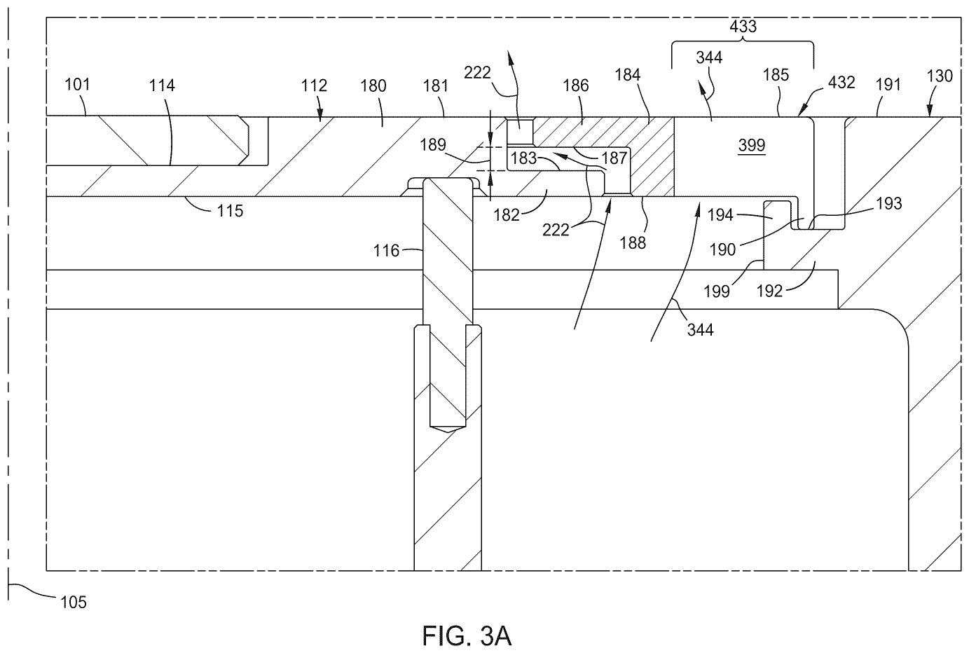

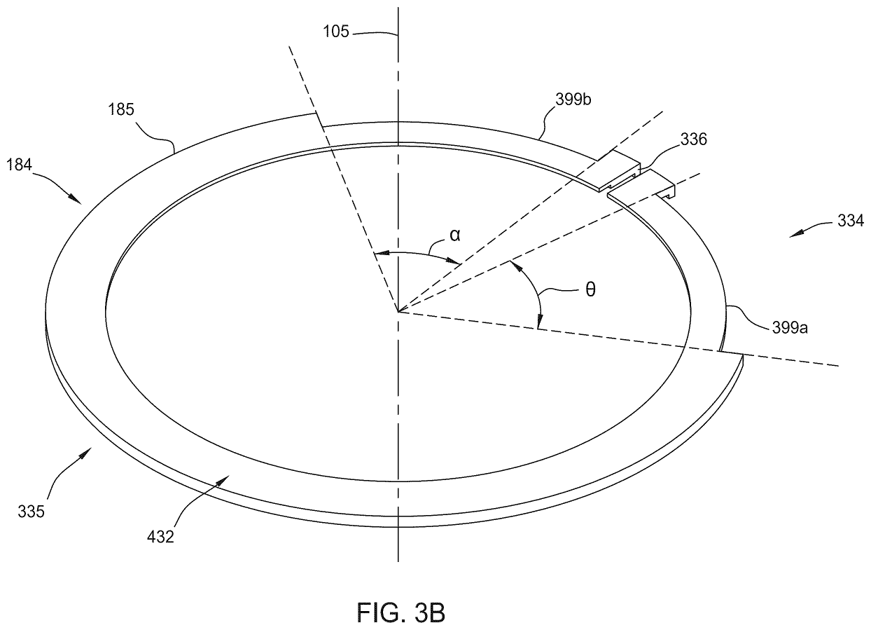

FIG. 3A is an enlarged cross-sectional view of portion A shown in FIG. 1 that shows another heater ring 432 that may be used in process chamber 100 according to some embodiments. The heater ring 432 may be substantially similar to the heater ring 132 previously described. Thus, the same reference numbers are used to refer to components of the heater ring 432 that are share with the heater ring 132. In addition, the following description will focus on the features of the heater ring 432 that are different from the heater ring 132.

As shown in FIG. 3A, the body 184 of the heater ring 432 also includes a vent portion 433 that includes an open slot 399 in place of the plurality of holes 212 of the vent portion 233 (FIG. 2A). Like the plurality of holes 212, the slot 399 of the vent portion 233 is also configured to improve the dynamic pressure balancing between the lower chamber 136 and the upper chamber 134 during operations. The slot 399 may extend radially inward from the radially outer edge of body 184 of heater ring 432 (specifically the outer flange 190) toward the inner flange 186. In addition, the slot 399 extends axially between the upper surface 185 and the lower surface 188. Thus, as may be appreciated in FIG. 3A, the slot 399 may define a separate fluid flow path 344 that is configured to allow fluid (such as purge gas) to flow from the lower chamber 136 to the upper chamber volume 134 independently of the gas flow path 222 between flanges 186, 182.

FIG. 3B is perspective view of the heater ring 432 of FIG. 3A according to some embodiments. The axis 105 of chamber body 102 is illustrated in FIG. 3B in a position corresponding to when the heater ring 432 is positioned in the chamber body 102 during operation. In some embodiments, the body 184 of preheat ring 432 includes a plurality of circumferentially spaced slots 399. For instance, as shown in FIG. 3B, the body 184 may include a first slot 399a and a second slot 399b that are circumferentially spaced from one another about axis 105.

In some embodiments, the first slot 399a may span circumferentially over the angle θ relative to axis 105, and the second slot 399b may span circumferentially over the angle α relative to axis 105. The angles θ and a may be the same or different, and may be within the ranges previously described above for the embodiment of heater ring 132 shown in FIG. 2B.

In addition, the first slot 399a and second slot 399b may be positioned in or along the first side 334 of the heater ring 432, wherein the first side 334 is aligned with the outlet port 142 (FIG. 1) as previously described. For instance, as previously described for the heater ring 432, the first slot 399a and second slot 399b may be entirely circumferentially contained in the first side 334, or may be mostly contained (that is, a majority of the span of the slots 399a, 399b may be contained) in or on the first side 334. In addition, the slit 336 may be circumferentially positioned between the slots 399a, 399b, and may be circumferentially centered between the slots 399a, 399b. In some embodiments, the slots 399a, 399b may have a total cross-sectional flow area in a radially oriented plane about axis 105 that is in a range of from about 1000 mm² to about 2000 mm², such as from about 1200 mm² to about 1400 mm², such as from about 1500 mm² to 1800 mm², such as from about 1600 mm² to about 1900 mm².

Referring back to FIGS. 3A and 3B, as explained above, the slots 399a, 399b may define separate fluid flow paths 344 that are configured to allow fluid (such as purge gas) to flow from the lower chamber volume 136 to the upper chamber volume 134 independently of the gas flow path 222 between flanges 186, 182. Thus, fluid flow paths 344 improve gas flow and dynamic pressure balancing between the upper portions 134 and the lower portion 136 of the processing chamber shown in FIG. 1 during operations. In addition, because the slot(s) 399 (or 399a, 399b) are positioned on or in the first radial side 334 of heater ring 132 that is further aligned with the outlet port 142, the additional flow paths 244 may be positioned proximate the outlet port 142. As a result, the additional flow of purge gas into the upper chamber 134 via the fluid flow paths 244 may be downstream of the substrate 101 relative to the flow of process gas in the upper chamber 134 so that this additional flow of purge gas may not interfere (or may not substantially interfere) with the deposition process as previously described.

Embodiments disclosed herein provide improved control of gas flow within processing chambers, particularly epitaxial processing chambers having process gas flow in an upper portion of the chamber and purge gas flow in a lower portion of the chamber. More specifically, embodiments disclosed herein may provide a vented heater ring which improves gas exchange between the process gas flow in the upper portion and purge gas flow in the lower portion of the processing chamber. Without being limited to this or any other theory, directly venting of purge gas flow from the lower portion of the chamber via embodiments of a vented heater ring disclosed herein provides an improved dynamic pressure balance between the upper and lower portions of the chamber that further improves deposition uniformity and tool uptime for an epitaxial deposition process. The preceding discussion is directed to various embodiments. However, one of ordinary skill in the art will understand that the examples disclosed herein have broad application, and that the discussion of any embodiment is meant only to be exemplary of that embodiment, and not intended to suggest that the scope of the disclosure, including the claims, is limited to that embodiment.

The drawing figures are not necessarily to scale. Certain features and components herein may be shown exaggerated in scale or in somewhat schematic form and some details of conventional elements may not be shown in interest of clarity and conciseness.

In the preceding discussion and in the claims, the terms “including” and “comprising” are used in an open-ended fashion, and thus should be interpreted to mean “including, but not limited to . . . . ” Also, the term “couple” or “couples” is intended to mean either an indirect or direct connection. Thus, if a first device couples to a second device, that connection may be through a direct connection of the two devices, or through an indirect connection that is established via other devices, components, nodes, and connections. In addition, as used herein, the terms “axial” and “axially” generally mean along or parallel to a given axis (e.g., central axis of a body or a port), while the terms “radial” and “radially” generally mean perpendicular to the given axis. For instance, an axial distance refers to a distance measured along or parallel to the axis, and a radial distance means a distance measured perpendicular to the axis. Further, when used herein (including in the claims), the words “about,” “generally,” “substantially,” “approximately,” and the like, when used to refer to a stated value, mean within a range of plus or minus 10% of the stated value.

While the foregoing is directed to embodiments of the present disclosure, other and further embodiments of the disclosure may be devised without departing from the basic scope thereof, and the scope thereof is determined by the claims that follow.

What is claimed is:

1. A processing chamber for a substrate, the processing chamber comprising:
a chamber body having a central axis and defining a processing region therein;
a liner positioned in the processing region;
a heater ring supported on the liner, the heater ring including an inner flange on a radially inner side thereof;
a susceptor positioned in the processing region, the susceptor including:
a top surface that is configured to support the substrate; and
a radially outer flange positioned radially outside of the top surface, the radially outer flange being at least partially radially overlapped with the inner flange of the heater ring; and
one or more axially oriented fluid flow paths that extend through the heater ring, wherein the one or more fluid flow paths are positioned radially outside of the inner flange.

2. The processing chamber of claim 1, wherein the processing chamber comprises:
a process gas inlet and a process gas outlet that are configured to direct a process gas through the processing region, above the susceptor and in a radial direction relative to the central axis; and
a purge gas inlet and a purge gas outlet that are configured to direct a purge gas through the lower chamber,
wherein the one or more fluid flow paths are configured to communicate purge gas through the heater ring.

3. The processing chamber of claim 2, wherein the process gas inlet is positioned on a first radial side of the chamber body and the process gas outlet is positioned on a second radial side of the chamber body that is radially opposite from the first radial side relative to the central axis, and wherein the one or more fluid flow paths through the heater ring are positioned on the second radial side.

4. The processing chamber of claim 1, wherein the one or more fluid flow paths are defined by a plurality of holes that extend axially through the heater ring.

5. The processing chamber of claim 4, wherein the plurality of holes are arranged in a first vent portion and a second vent portion on a body of the heater ring so that a first subset of the plurality of holes are arranged in the first vent portion and a second subset of the plurality of holes are arranged in the second vent portion, wherein the first vent portion and the second vent portion are circumferentially spaced from one another about the central axis.

6. The processing chamber of claim 5, wherein the first subset of the plurality of holes in the first vent portion span circumferentially along an angle θ relative to the central axis, wherein the second subset of the plurality of holes in the second vent portion span circumferentially along an angle α relative to the central axis, wherein the angles θ and a are less than 90°.

7. The processing chamber of claim 6, wherein the angle θ and the angle α are different.

8. The processing chamber of claim 6, wherein the angle θ and the angle α are the same.

9. The processing chamber of claim 3, wherein the one or more fluid flow paths are defined by one or more slots defined along a radially outer edge of the heater ring.

10. The processing chamber of claim 9, wherein the one or more slots comprises a first slot and a second slot circumferentially spaced from the first slot about the central axis.

11. The processing chamber of claim 10, wherein the first slot and the second slot both span less than 90° about the central axis, and wherein both the first slot and the second slot are positioned on the first radial side of the chamber body.

12. A heater ring for a substrate processing chamber, the heater ring comprising:
a body having a central axis, an upper surface, and a lower surface opposite the upper surface along the central axis;
an inner flange defined on a radially inner side of the body relative to the central axis;
a radially outer flange defined on a radially outer side of the body relative to the central axis; and
one or more fluid flow paths extending axially between the upper surface and the lower surface that are radially positioned between the inner flange and the radially outer flange.

13. The heater ring of claim 12, wherein the inner flange extends radially inward from the radially inner side of the body, and wherein the radially outer flange extends axially outward from the lower surface.

14. The heater ring of claim 13, wherein the one or more fluid flow paths comprise a plurality of holes that extend axially between the upper surface and the lower surface.

15. The heater ring of claim 14, wherein a first subset of the plurality of holes are arranged in a first vent portion on the body and a second subset of the plurality of holes are arranged in a second vent portion on the body, wherein the first vent portion and the second vent portion are circumferentially spaced from one another about the central axis, and wherein the first vent portion and the second vent portion are both contained on a first radial side of the body, the first radial side of the body being radially opposite a second radial side of the body.

16. The heater ring of claim 15, wherein the body includes a radially extending slit that is positioned circumferentially between the first vent portion and the second vent portion about the central axis.

17. The heater ring of claim 13, wherein the one or more fluid flow paths comprise one or more slots defined on a radially outer edge of the body.

18. The heater ring of claim 17, wherein the one or more slots comprise a first slot and a second slot, wherein the first slot and the second slot are circumferentially spaced from one another about the central axis, and wherein the first slot and the second slot are both contained on a first radial side of the body, the first radial side of the body being radially opposite a second radial side of the body.

19. A processing chamber for a substrate, the processing chamber comprising:
a chamber body having a central axis and defining a processing region therein, the chamber body further comprising:
a process gas inlet on a first radial side of the chamber body; and
a process gas outlet on a second radial side of the chamber body, the second radial side of the chamber body being radially opposite the first radial side of the chamber body;
a heater ring supported in the processing region, the heater ring including an inner flange on a radially inner side thereof;
a susceptor configured to support the substrate, the susceptor dividing the processing region into an upper chamber axially above the heater ring and a lower chamber below the heater ring;
a first flow path between the lower chamber and the upper chamber that is at least partially defined between the heater ring and the susceptor; and
one or more second fluid flow paths between the lower chamber and the upper chamber that extend vertically through the heater ring, wherein the one or more second fluid flow paths are positioned on the second radial side of the chamber body.

20. The processing chamber of claim 19, wherein the one or more second fluid flow paths comprise at least one of:
a plurality of holes extending axially through the heater ring; or
one or more slots defined on a radially outer edge of the heater ring.
